(19) United States
(12) Patent Application Publication
(10) Pub. No.: US 2026/0314310 A1
(43) Pub. Date: Oct. 8, 2026

(54) SUBSTRATE MARKING APPARATUS AND SUBSTRATE MARKING METHOD USING THE SAME

(71) Applicant: Samsung Electronics Co., Ltd., Suwon-si (KR)

(72) Inventors: Jinoh Jung, Suwon-si (KR); Jeehee Yoon, Suwon-si (KR); Seonhoo Kim, Suwon-si (KR); Yong Deok Jeong, Suwon-si (KR)

(73) Assignee: Samsung Electronics Co., Ltd., Suwon-si (KR)

(21) Appl. No.: 19/531,441

(22) Filed: Feb. 5, 2026

(30) Foreign Application Priority Data
Apr. 8, 2025 (KR) 10-2025-0045398
May 29, 2025 (KR) 10-2025-0070768

(51) Int. Cl. H10P 72/00; H10P 72/50

(52) U.S. Cl. CPC H10P 72/0614; H10P 72/0604; H10P 72/53

(57) ABSTRACT

Provided is a substrate marking apparatus. The substrate marking apparatus includes a stage configured to support a substrate, a camera-marking assembly on the stage, movement devices configured to move the camera-marking assembly, and a controller electrically connected to the camera-marking assembly and the movement devices, wherein the camera-marking assembly includes a main body connected to the movement devices, a marking device adjacent to the stage, and a pressure sensor coupled to the main body.

### CROSS-REFERENCE TO RELATED APPLICATIONS

This present application claims priority to and the benefit under 35 U.S.C. §119(a)-(d) of Korean Patent Application No. 10-2025-0045398, filed on Apr. 8, 2025, in the Korean Intellectual Property office, and Korean Patent Application No. 10-2025-0070768, filed on May 29, 2025, in the Korean Intellectual Property office, the entire disclosures of which are incorporated herein by reference.

### FIELD

The present disclosure herein relates to a substrate marking apparatus and a substrate marking method using the same, and more particularly, to a substrate marking apparatus that efficiently marks chips on a substrate without contaminating the chips, and a substrate marking method using the substrate marking apparatus.

### BACKGROUND

As semiconductor devices become more highly integrated and reduced in size, chip analysis is becoming increasingly important to analyze defects and failures that occur during process development and mass production, as well as to verify circuits. In a chip analysis method according to the related art in which marking is performed by a magic marker on the outside of a chip or on a package, analysts have to manually search for locations thereof because the method is not precise and does not work with automated equipment. Also, a laser engraving method as one of the alternatives to the technique described above has the risk of contaminating analysis chips with dust. Therefore, there is an increasing need for a marking method that specifies an exact analysis location on a chip in advance and precisely recognizes the location.

### SUMMARY

The present disclosure provides a substrate marking apparatus that does not contaminate a chip and a substrate marking method using the substrate marking apparatus.

The present disclosure also provides a substrate marking apparatus that efficiently marks chips and a substrate marking method using the substrate marking apparatus.

The objectives of the disclosed concepts are not limited to those stated above, and other objectives not described herein may be understood by those skilled in the art from the following descriptions.

Embodiments of the disclosed concepts provide a substrate marking apparatus including a stage configured to support a substrate, a camera-marking assembly on the stage, movement devices configured to move the camera-marking assembly, and a controller electrically connected to the camera-marking assembly and the movement devices, wherein the camera-marking assembly includes a main body connected to the movement devices, a marking device adjacent to the stage, and a pressure sensor coupled to the main body.

In embodiments of the disclosed concepts, a substrate marking method includes preparing a substrate with a substrate marking apparatus, identifying locations of the substrate and an analysis chip, forming a temporary boundary line surrounding the analysis chip, forming a boundary line from the temporary boundary line, and marking the substrate along the boundary line, wherein the substrate marking apparatus includes a camera-marking assembly including a camera and a marking device, movement devices connected to the camera-marking assembly, and a controller electrically connected to the camera-marking assembly and the movement devices.

In embodiments of the disclosed concepts, a substrate marking system includes a load port configured to support a front opening unified pod (FOUP) for storing a substrate, a chamber connected to the load port and including a substrate marking apparatus, and an interface module between the load port and the chamber, wherein the substrate marking apparatus includes a stage configured to support a substrate, a camera-marking assembly on the stage, and movement devices configured to move the camera-marking assembly, and wherein the camera-marking assembly includes a marking device, a pressure sensor, and a camera.

### BRIEF DESCRIPTION OF THE DRAWINGS

The accompanying drawings are included to provide a further understanding of the disclosed concepts, and are incorporated in and constitute a part of this specification. The drawings illustrate embodiments of the disclosed concepts and, together with the description, serve to explain principles of the disclosed concepts. In the drawings:

FIG. 1 is a perspective view illustrating a substrate marking apparatus according to embodiments of the disclosed concepts;

FIG. 2 is a plan view illustrating a substrate marking apparatus according to embodiments of the disclosed concepts;

FIG. 3 is a front view illustrating a substrate marking apparatus according to embodiments of the disclosed concepts;

FIG. 4 is a front view illustrating a state in which a substrate marking apparatus according to embodiments of the disclosed concepts is marking a substrate;

FIG. 5 is an enlarged view of region X of FIG. 4;

FIG. 6 is a plan view illustrating a substrate marking system according to embodiments of the disclosed concepts;

FIG. 7 is a flowchart illustrating a substrate marking method according to embodiments of the disclosed concepts; and

FIGS. 8 to 12 are diagrams illustrating the substrate marking method according to embodiments of the disclosed concepts.

### DETAILED DESCRIPTION

Hereinafter, embodiments of the disclosed concepts are described in detail with reference to the accompanying drawings. Like reference numerals refer to like elements throughout.

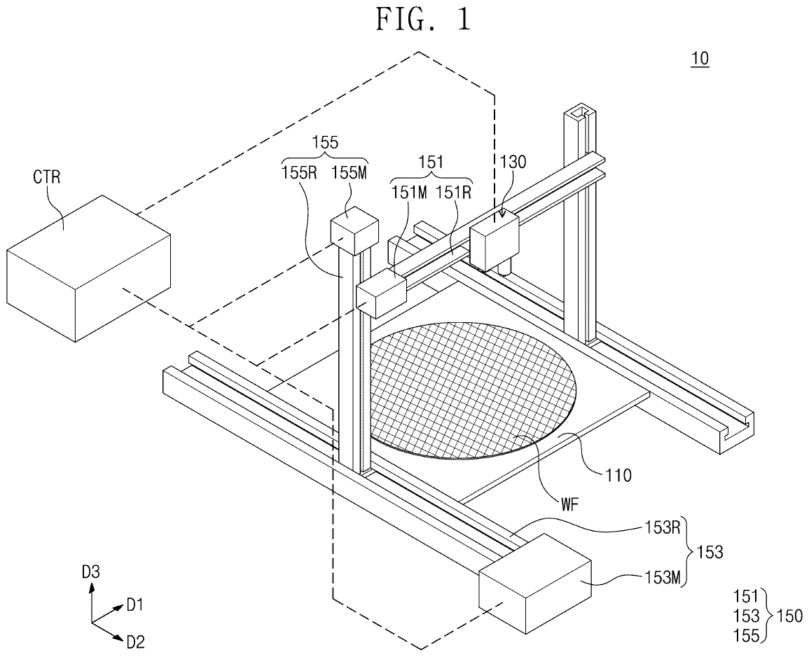

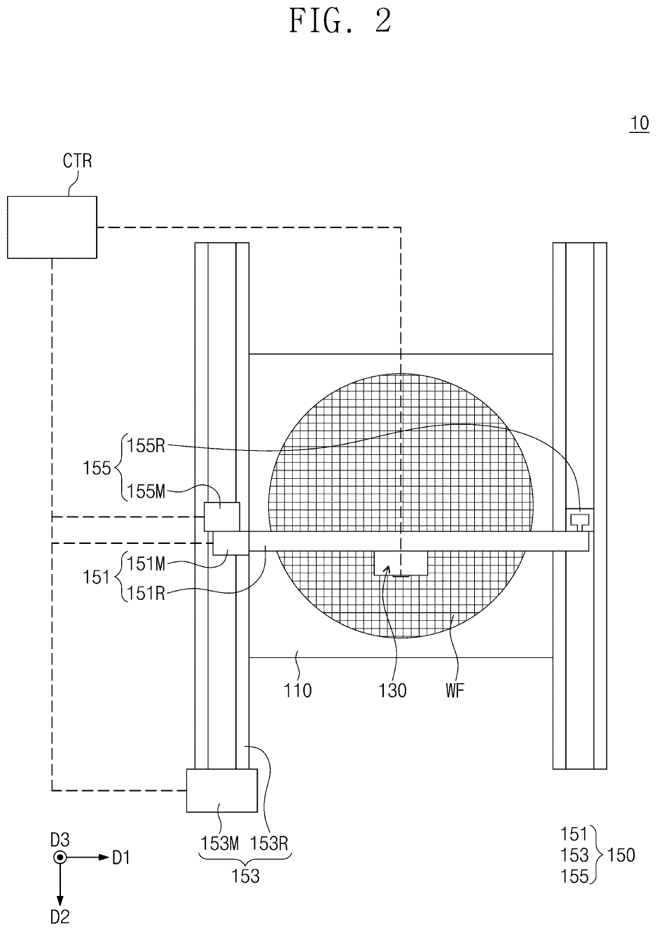

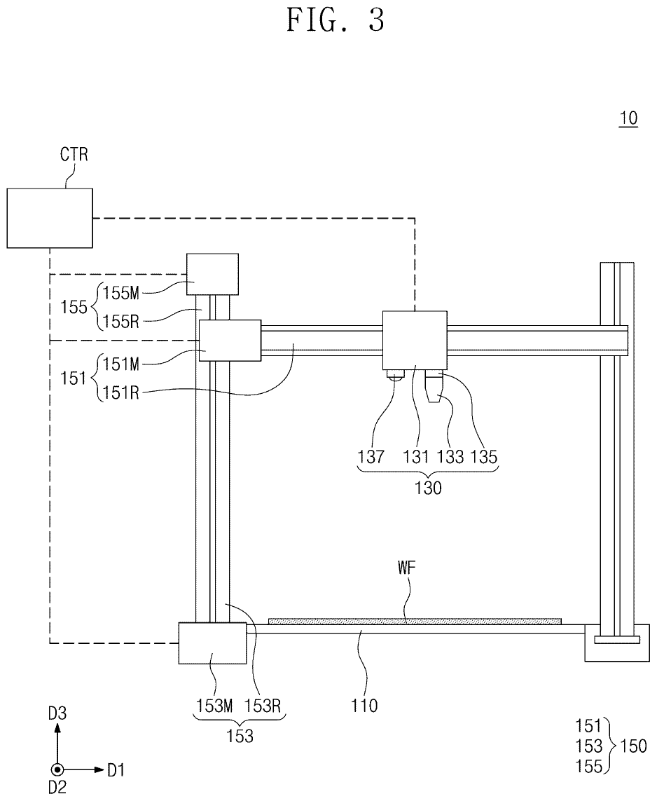

FIG. 1 is a perspective view illustrating a substrate marking apparatus according to embodiments of the disclosed concepts. FIG. 2 is a plan view illustrating a substrate marking apparatus according to embodiments of the disclosed concepts. FIG. 3 is a front view illustrating a substrate marking apparatus according to embodiments of the disclosed concepts.

Referring to FIGS. 1, 2, and 3, a substrate marking apparatus 10 may be provided. As used herein, the substrate marking apparatus 10 may represent a facility for marking chips arranged on a substrate WF. The substrate WF may represent a silicon (Si) wafer, but embodiments of the disclosed concepts is not limited thereto. Also, the chips may include memory devices, such as volatile memory devices and non-volatile memory devices, and/or logic devices, such as AND, OR, XOR, XNOR, and inverters. For example, the substrate marking apparatus 10 may include a stage 110, a camera-marking assembly 130, movement devices 150, and a controller CTR.

The stage 110 of the substrate marking apparatus 10 may be located on a lower side of the substrate marking apparatus 10. The stage 110 may be configured to support the substrate WF. For example, the substrate WF may be disposed on the stage 110 such that an upper surface of the substrate WF is parallel to a first direction D1 and a second direction D2. Also, the stage 110 may hold the substrate WF disposed thereon. Accordingly, the substrate WF may not move on the stage 110. According to embodiments, the stage 110 may include an electrostatic chuck that utilizes electrostatic forces to hold the substrate WF. According to embodiments, the stage 110 may include a vacuum chuck that utilizes a vacuum to hold the substrate WF. According to embodiments, the stage 110 may include a clamp that physically holds the substrate WF.

According to embodiments, the first direction D1 and the second direction D2 may intersect one another. A third direction D3 may intersect the first direction D1 and the second direction D2 and may be perpendicular to the upper surface of the substrate WF. For example, the first direction D1, the second direction D2, and the third direction D3 may be perpendicular to one another. As used herein, the first direction D1 and the second direction D2 may be referred to as the horizontal directions, and the third direction D3 may be referred to as the vertical direction.

The movement devices 150 of the substrate marking apparatus 10 may be located adjacent to the stage 110. The movement devices 150 may be configured to move the camera-marking assembly 130. For example, the movement devices 150 may include a first movement device 151, a second movement device 153, and a third movement device 155, which extend in different directions.

The first movement device 151 may be located on the stage 110 and the substrate WF. The first movement device 151 may be spaced apart from the stage 110 and the substrate WF in the third direction D3. The first movement device 151 may include a first rail 151R and a first drive unit 151M. The first rail 151R may extend in the first direction D1. The first drive unit 151M may be coupled to one side of the first rail 151R. The first drive unit 151M may be electrically connected to the controller CTR and controlled by the controller CTR. For example, the first drive unit 151M may receive an electrical signal from the controller CTR and move the camera-Attorney marking assembly 130 coupled to the first rail 151R in the first direction D1 (or in a direction opposite to the first direction D1).

The second movement device 153 may be positioned on a side surface of the stage 110. The second movement device 153 may include a second rail 153R and a second drive unit 153M. The second rail 153R may extend in the second direction D2. For example, the second rail 153R may be provided in a pair, and the pair of second rails 153R may individually extend in the second direction D2 on both sides of the stage 110. The second drive unit 153M may be coupled to one side of the second rail 153R. The second drive unit 153M may be electrically connected to the controller CTR and controlled by the controller CTR. For example, the second drive unit 153M may receive an electrical signal from the controller CTR and move a third rail 155R of the third movement device 155 coupled to the second rail 153R, in the second direction D2 (or in a direction opposite to the second direction D2).

The third movement device 155 may be located between the first movement device 151 and the second movement device 153 and connect the first movement device 151 to the second movement device 153. The third movement device 155 may include the third rail 155R and a third drive unit 155M. The third rail 155R may extend in the third direction D3. For example, the third rail 155R may be provided in a pair, and the pair of third rails 155R may individually extend in the third direction D3 on the second rails 153R. The third drive unit 155M may be coupled to one side of the third rail 155R. The third drive unit 155M may be electrically connected to the controller CTR and controlled by the controller CTR. For example, the third drive unit 155M may receive an electrical signal from the controller CTR and move the first rail 151R coupled to the third rail 155R, in the third direction D3 (or in a direction opposite to the third direction D3).

In other words, the camera-marking assembly 130 may be moved in the first direction D1 by the first movement device 151. The camera-marking assembly 130 may be moved in the second direction D2 by the second movement device 153. The camera-marking assembly 130 may be moved in the third direction D3 by the third movement device 155. That is, the camera-marking assembly 130 may be moved in three dimensions on the stage 110 by the movement devices 150. According to embodiments, each of the first drive unit 151M, the second drive unit 153M, and the third drive unit 155M may include a motor and/or a conveyor belt.

The camera-marking assembly 130 may be located on the stage 110. The camera-marking assembly 130 may include a main body 131, a marking device 133, a pressure sensor 135, and a camera 137. The main body 131 of the camera-marking assembly 130 may be coupled to the marking device 133, the pressure sensor 135, and the camera 137 to support the same. The main body 131 may include an electronic device therein that transmits electrical signals to and receives electrical signals from the controller CTR. For example, the electronic device of the main body 131 may be configured to provide the controller CTR with data about the pressure measured by the pressure sensor 135 and the image of the substrate WF measured by the camera 137.

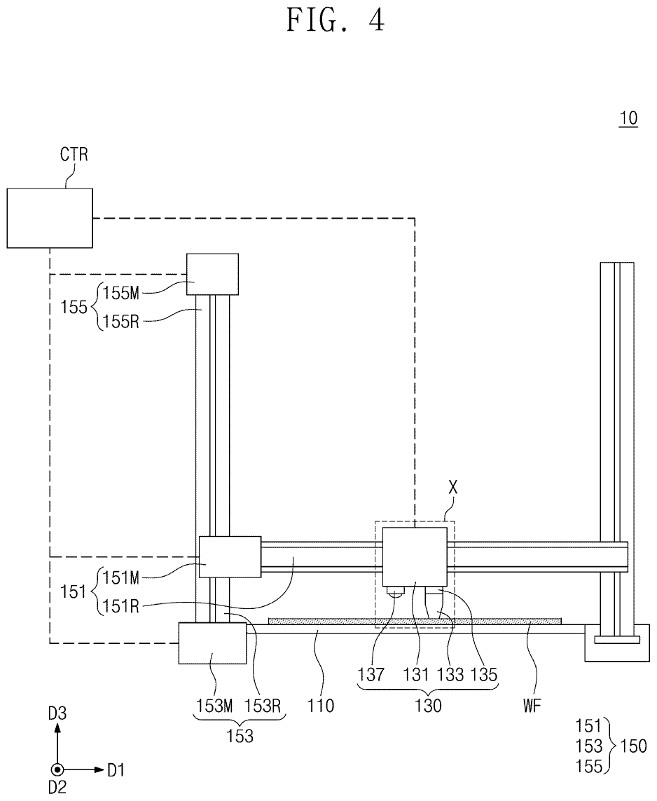

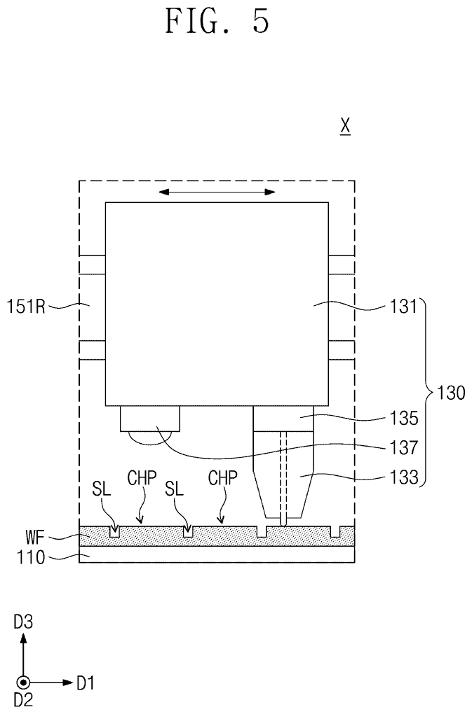

The marking device 133 of the camera-marking assembly 130 may be connected to a lower portion of the main body 131 such that the marking device 133 is adjacent to the stage 110 and the substrate WF. The pressure sensor 135 of the camera-marking assembly 130 may be positioned between the marking device 133 and the main body 131 and coupled to the lower portion of the main body 131. The camera 137 of the camera-marking assembly 130 may be spaced apart from the marking device 133 and the pressure sensor 135 and coupled to the lower portion of the main body 131. The marking device 133, the pressure sensor 135, and the camera 137 of the camera-marking assembly 130 are described in more detail with reference to FIGS. 4 and 5.

The controller CTR may be located in a space separate from the stage 110, but embodiments of the disclosed concepts are not limited thereto. The controller CTR may be electrically connected to the camera-marking assembly 130, the first drive unit 151M of the first movement device 151, the second drive unit 153M of the second movement device 153, and the third drive unit 155M of the third movement device 155. For example, the controller CTR may receive data (e.g., pressure and images, etc.) from the camera-marking assembly 130. Based on the data received from the camera-marking assembly 130, the controller CTR may transmit electrical signals to the first drive unit 151M, the second drive unit 153M, and the third drive unit 155M. For example, the controller CTR may control the first drive unit 151M, the second drive unit 153M, and the third drive unit 155M to move the camera-marking assembly 130 in the first direction D1, the second direction D2, and/or the third direction D3.

To this end, the controller CTR may include a variety of components. For example, the controller CTR may include one or more central processing units (CPUs) configured to execute computer program instructions so as to perform various processes and methods, memory devices configured to access and store data and instructions, and input/output devices configured to provide inputs and/or outputs. Also, the controller CTR may include a network interface for providing a digital and/or analog interface to one or more networks in a wired and/or wireless manner and an antenna for wireless communication, and may include a power unit for providing power to each of components of the controller CTR and a bus for exchanging data and signals between the components.

FIG. 4 is a front view illustrating a state in which a substrate marking apparatus according to embodiments of the disclosed concepts is marking a substrate. FIG. 5 is an enlarged view of region X of FIG. 4.

Hereinafter, for convenience of description, repeated descriptions as those given with reference to FIGS. 1 to 3 are omitted, and the differences therebetween are described in detail.

Referring to FIGS. 4 and 5, the substrate WF may include scribe lines SL and chips CHP. Each of the scribe lines SL may extend in the first direction D1 or the second direction D2. The scribe lines SL may recess an upper portion of the substrate WF to separate adjacent chips CHP from one another. For example, the chips CHP may be arranged between the scribe lines SL, and the chips CHP of the substrate WF may be defined by the scribe lines SL. Accordingly, a bottom surface of each of the scribe lines SL may be at a lower level than an upper surface of each of the chips CHP. As used herein, the term “level” may represent a height (or a length) in the third direction D3 from the upper surface of the stage 110 or the bottom surface of the substrate WF. That is, the substrate WF is not flat and may have the upper surface with stepped regions.

The camera 137 of the camera-marking assembly 130 may include an image sensor, and a lens, etc. The camera 137 may identify the locations of the scribe lines SL and the chips CHP of the substrate WF, and may transmit data about the image of the substrate WF to the controller CTR. To this end, the camera-marking assembly 130 may be moved on the stage 110 in the first direction D1 and/or the second direction D2 by the first movement device 151 and/or the second movement device 153.

In order to mark the substrate WF, the camera-marking assembly 130 may be located adjacent to the substrate WF. The camera-marking assembly 130 may be lowered by the third movement device 155, and thus, the marking device 133 of the camera-marking assembly 130 may be brought into contact with the substrate WF on the stage 110. While the marking device 133 is in contact with the substrate WF, the camera-marking assembly 130 may be moved in the first direction D1 and/or the second direction D2 by the first movement device 151 and/or the second movement device 153. Accordingly, the marking device 133 may mark the substrate WF while passing through the scribe lines SL and the chips CHP of the substrate WF. The marking device 133 may be configured to eject ink in an inkjet method. In the inkjet method, the substrate WF is not partially etched or removed to mark the substrate WF, and thus, contaminating particles (or dust) may not be generated. Therefore, the substrate marking apparatus 10 may prevent the substrate WF from being contaminated due to the marking.

The marking device 133 of the camera-marking assembly 130 may include a tip at a lower end thereof. The tip of the marking device 133 may come into contact with the substrate WF and press the substrate WF at constant pressure. The pressure between the marking device 133 and the substrate WF may be measured by the pressure sensor 135 between the marking device 133 and the main body 131. For example, when the pressure between the marking device 133 and the substrate WF excessively increases, the chips CHP of the substrate WF may be damaged by the tip of the marking device 133. On the other hand, when the pressure between the marking device 133 and the substrate WF significantly decreases, the marking device 133 may not sufficiently mark the substrate WF. That is, constant and adequate pressure may be required between the marking device 133 and the substrate WF to sufficiently mark the substrate WF without damaging the chips CHP of the substrate WF.

According to embodiments, the marking device 133 of the camera-marking assembly 130 may move from the chips CHP of the substrate WF to the scribe lines SL. Since the bottom surfaces of the scribe lines SL are at a lower level than the upper surfaces of the chips CHP, the pressure between the marking device 133 and the substrate WF may suddenly decrease. In this case, the camera-marking assembly 130 may provide the controller CTR with data about the pressure between the marking device 133 and the substrate WF. Based on data about the pressure received from the camera-marking assembly 130, the controller CTR may control the third drive unit 155M of the third movement device 155 to lower the camera-marking assembly 130 so that the pressure between the marking device 133 and the substrate WF increases.

According to embodiments, the marking device 133 of the camera-marking assembly 130 may move from the scribe lines SL of the substrate WF to the chips CHP. Since the upper surfaces of the chips CHP are at a higher level than the bottom surfaces of the scribe lines SL, the pressure between the marking device 133 and the substrate WF may suddenly increase. In this case, the camera-marking assembly 130 may provide the controller CTR with data about the pressure between the marking device 133 and the substrate WF. Based on data about the pressure received from the camera-marking assembly 130, the controller CTR may control the third drive unit 155M of the third movement device 155 to raise the camera-marking assembly 130 so that the pressure between the marking device 133 and the substrate WF decreases.

In other words, the camera-marking assembly 130 may provide the controller CTR with data about the pressure between the marking device 133 and the substrate WF in real time. Based on the data about the pressure between the marking device 133 and the substrate WF received from the camera-marking assembly 130, the controller CTR may control the third drive unit 155M of the third movement device 155 in real time. Accordingly, the pressure between the marking device 133 and the substrate WF may be controlled in real time. Therefore, the substrate marking apparatus 10 may efficiently mark the substrate WF while preventing or minimizing damage to the chips CHP of the substrate WF.

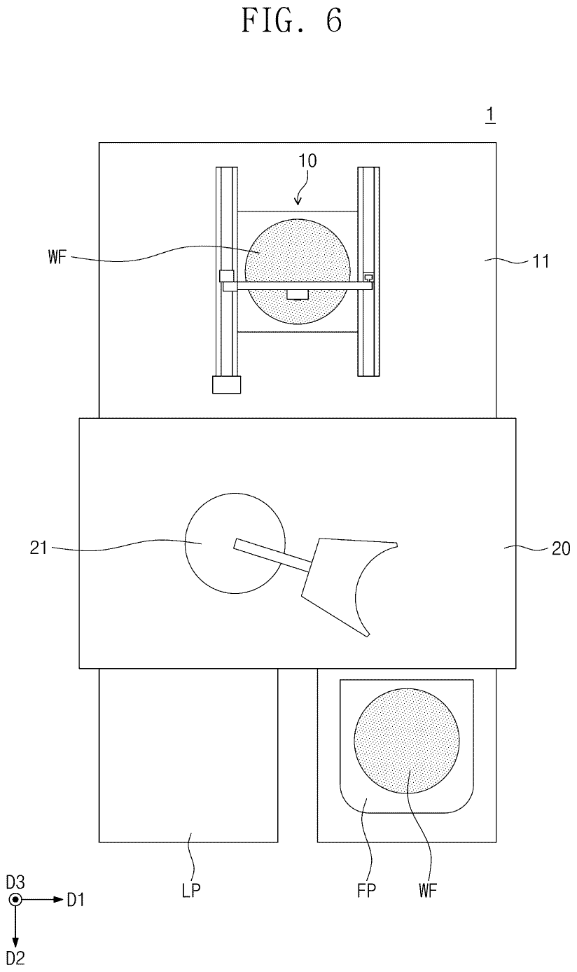

FIG. 6 is a plan view illustrating a substrate marking system according to embodiments of the disclosed concepts.

Referring to FIG. 6, a substrate marking system 1 may be provided. For example, the substrate marking system 1 may represent one automated system that includes a plurality of apparatuses capable of marking the substrate WF. The substrate marking system 1 may include a load port LP, an interface module 20, and a chamber 11.

The load port LP may position a front opening unified pod (FOUP) FP that stores the substrate WF. When the FOUP FP is positioned on the load port LP, the load port LP may hold the FOUP FP. The load port LP may be docked such that the FOUP FP comes into contact with the interface module 20. The substrate WF inside the FOUP FP may enter or exit the substrate marking system 1 through the load port LP. The number of load ports LP may vary.

The interface module 20 may be located between the load port LP and the chamber 11. The interface module 20 may connect the load port LP to the chamber 11. The load port LP may be spaced apart from the chamber 11 with the interface module 20 therebetween. The interface module 20 may include a robot arm 21 therein. The robot arm 21 of the interface module 20 may convey the substrate WF in the FOUP FP to the chamber 11. Also, the robot arm 21 of the interface module 20 may convey the substrate WF in the chamber 11 to the FOUP FP.

The chamber 11 may be located on one side of the interface module 20. The chamber 11 may include the substrate marking apparatus 10 therein. The substrate marking apparatus 10 may include a stage for supporting a substrate, a camera-marking assembly, a movement device for moving the camera-marking assembly, and a controller for controlling the movement device. For example, the substrate marking apparatus 10 may be substantially the same as that described with reference to FIGS. 1 to 3.

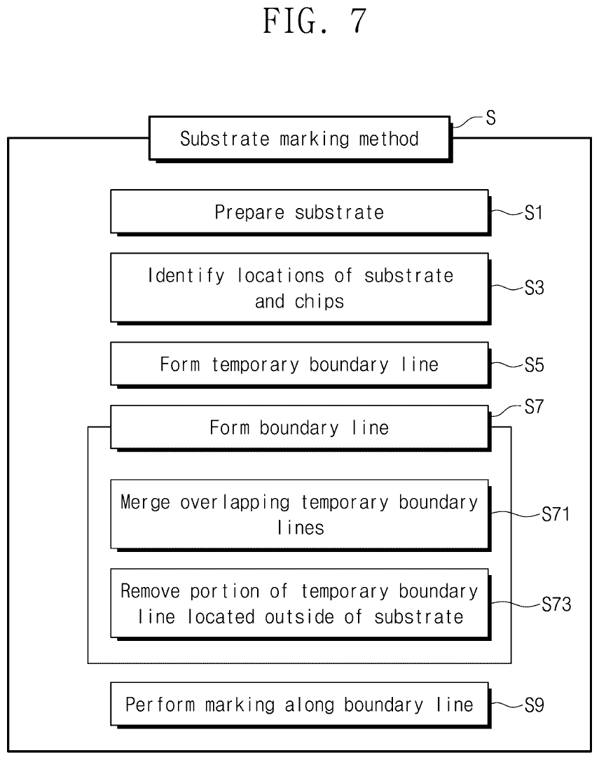

FIG. 7 is a flowchart illustrating a substrate marking method according to embodiments of the disclosed concepts.

Referring to FIG. 7, a substrate marking method S may be provided. The substrate marking method S according to the disclosed concepts may represent a method for marking chips arranged on a substrate by using the substrate marking apparatus 10 or the substrate marking system 1 described with reference to FIGS. 1 to 6. The substrate marking method S may include preparing a substrate (S1), identifying locations of the substrate and chips (S3), forming a temporary boundary line (S5), forming a boundary line (S7), and performing marking along the boundary line (S9).

Also, the forming of the boundary line (S7) may include merging overlapping temporary boundary lines (S71) and removing a portion of the temporary boundary line that is located outside of the substrate (S73).

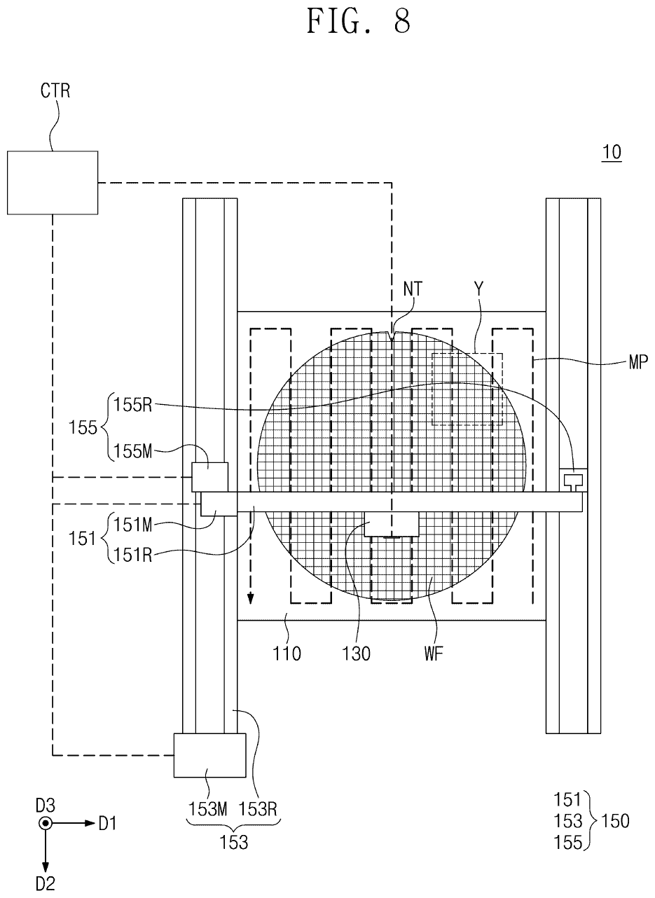

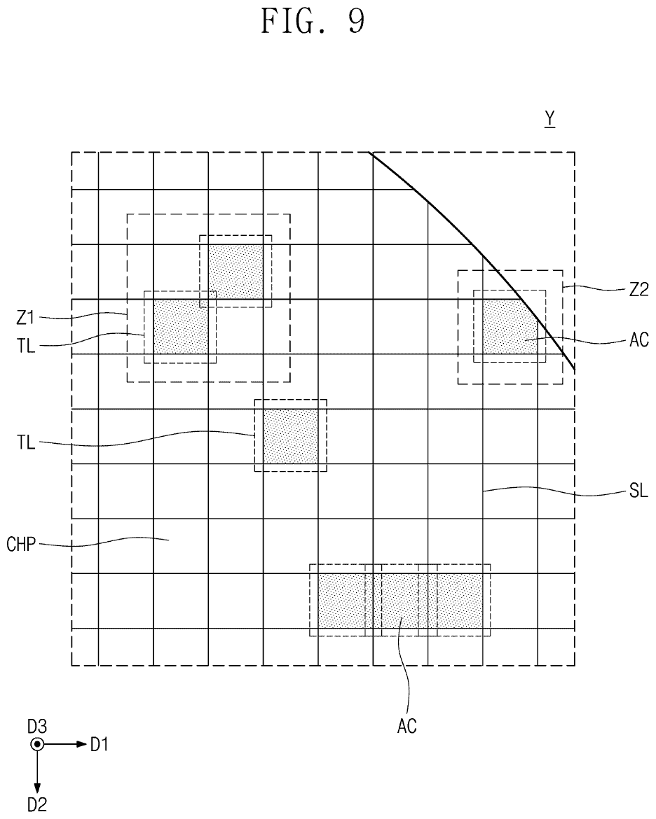

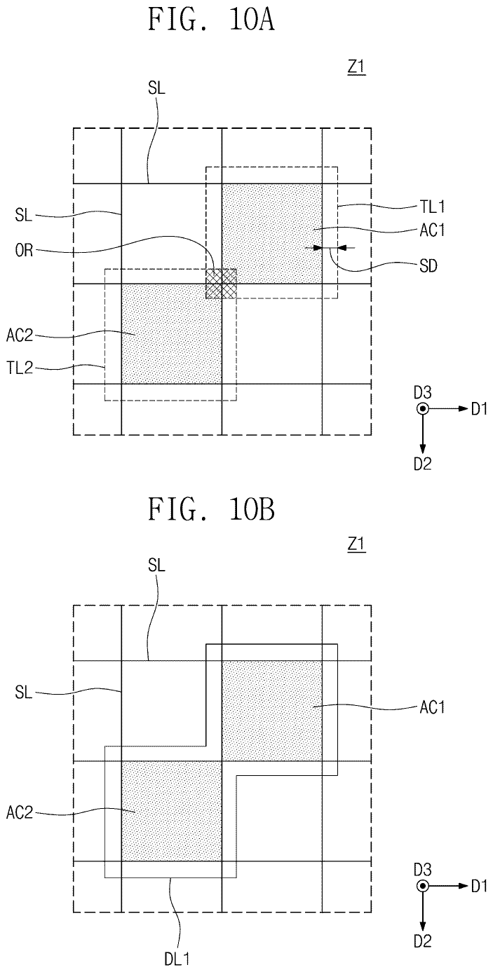

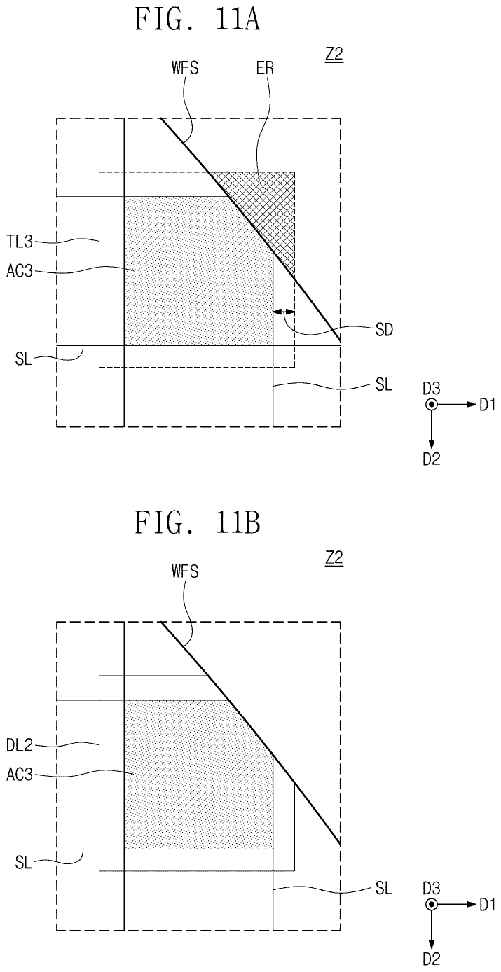

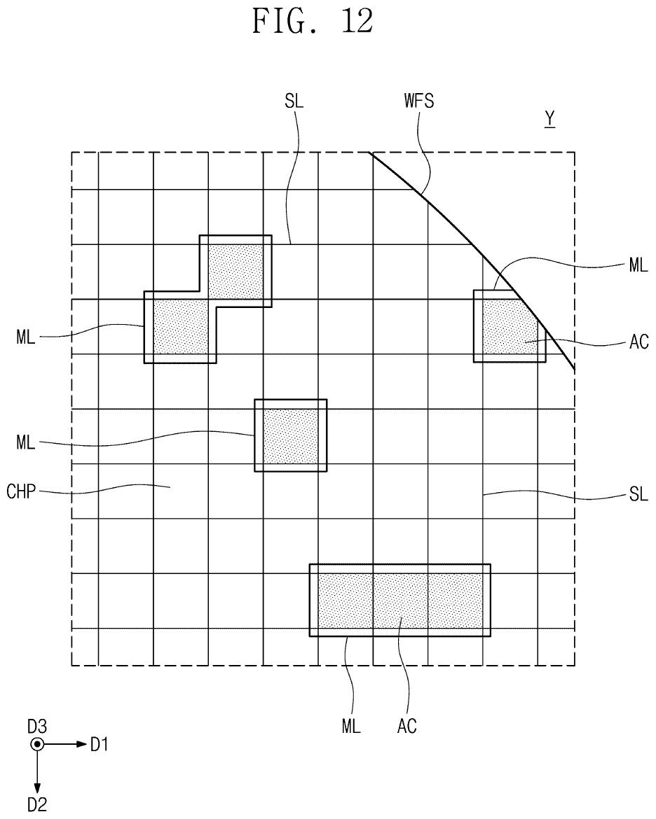

FIGS. 8 to 12 are diagrams illustrating the substrate marking method according to embodiments of the disclosed concepts. FIG. 8 is a plan view illustrating a substrate marking apparatus according to embodiments of the disclosed concepts. FIG. 9 is an enlarged view of region Y of FIG. 8. FIGS. 10A and 10B are enlarged views of region Z1 of FIG. 9. FIGS. 11A and 11B are enlarged views of region Z2 of FIG. 9. FIG. 12 is an enlarged view of region Y of FIG. 8.

Referring to FIGS. 7 and 8, the preparing of the substrate (S1) may include arranging the substrate WF on the stage 110 of the substrate marking apparatus 10 and holding the substrate WF by the stage 110. For example, the substrate WF may be manually placed on the stage 110 by a user. Alternatively, the substrate WF may be automatically placed on the stage 110 by the substrate marking system 1 described with reference to FIG. 6. After the substrate WF is placed on the stage 110, the stage 110 may hold the substrate WF by utilizing electrostatic forces, vacuum pressure, or physical bonding.

Referring to FIGS. 7, 8, and 9, the identifying of the locations of the substrate and chips (S3) may include moving the camera-marking assembly 130. The moving of the camera-marking assembly 130 may include moving the camera-marking assembly 130 in the first direction D1 by the first movement device 151 and moving the camera-marking assembly 130 in the second direction D2 by the second movement device 153. Accordingly, the camera-marking assembly 130 may move in two dimensions on the stage 110. The camera of the camera-marking assembly 130 may identify an entire surface of the substrate WF and provide the controller CTR with the data about the image of the substrate WF. In a plan view, a movement path MP of the camera-marking assembly 130 may have a zigzag form, but embodiments of the disclosed concepts are not limited thereto.

According to embodiments, the identifying of the location of the substrate WF may be identifying a notch NT of the substrate WF. The notch NT of the substrate WF may be a groove formed by removing a portion of the edge of the substrate WF. In a plan view, the notch NT of the substrate WF may have a V-shape or a U-shape. For example, the camera of the camera-marking assembly 130 may identify the notch NT of the substrate WF, and the camera-marking assembly 130 may provide the controller CTR with the data about the location of the notch NT. After that, the controller CTR may then identify the locations of the chips CHP based on the notch NT of the substrate WF.

According to embodiments, the identifying of the locations of the chips CHP may be identifying the scribe lines SL of the substrate WF. For example, the camera of the camera-marking assembly 130 may identify the scribe lines SL that extend in the first direction D1 or the second direction D2 based on the notch NT of the substrate WF. Accordingly, the locations of the chips CHP in the substrate WF defined by the scribe lines SL may be identified.

The forming of the temporary boundary line (S5) may include identifying the locations of analysis chips AC and virtually forming temporary boundary lines TL that surround the analysis chips AC using the controller CTR. The chips CHP of the substrate WF may include the analysis chips AC. For example, the analysis chips AC may be defective chips selected from other semiconductor measurement apparatus, or the analysis chips AC may be chips present at specific locations selected by the user.

The identifying of the locations of the analysis chips AC may be performed by the controller CTR. In the identifying of the locations of the substrate and chips (S3), the controller CTR may identify the locations of the analysis chips AC based on the image of the substrate WF provided by the camera-marking assembly 130 to the controller CTR. For example, the controller CTR may identify the locations of the analysis chips AC of the substrate WF by comparing the image of the substrate WF received from the camera-marking assembly 130 with the locations of chips selected by other semiconductor measurement apparatus or by a user.

After that, the controller CTR may form the temporary boundary lines TL that respectively surround the analysis chips AC of which the locations have been identified. The temporary boundary lines TL may be spaced apart from the corresponding analysis chips AC and may not overlap the analysis chips AC. For example, the temporary boundary lines TL may be virtual boundary lines formed by a program in the controller CTR based on an image of the substrate WF. That is, the temporary boundary lines TL may be a virtual image formed in the program of the controller CTR, and the forming of the temporary boundary lines (S5) may not be a direct marking of the substrate WF.

Referring to FIGS. 7, 10A, and 10B, a first temporary boundary line TL1 surrounding a first analysis chip AC1 and a second temporary boundary line TL2 surrounding a second analysis chip AC2 may be formed. The first analysis chip AC1 and the second analysis chip AC2 may be adjacent to one another. For example, the first analysis chip AC1 and the second analysis chip AC2 may be adjacent to one another in a diagonal direction between the first direction D1 and the second direction D2.

The first temporary boundary line TL1 may be spaced apart from edges of the first analysis chip AC1 in the first direction D1 and the second direction D2. For example, a separation distance SD between the first temporary boundary line TL1 and the first analysis chip AC1 may be about 3 mm. A first temporary boundary region defined by the first temporary boundary line TL1 may be formed larger than the first analysis chip AC1. For example, a planar size of the first temporary boundary region may be larger than a planar size of the first analysis chip AC1. Similarly, a planar size of the second temporary boundary region defined by the second temporary boundary line TL2 may be larger than a planar size of the second analysis chip AC2. As a result, the first temporary boundary line TL1 and the second temporary boundary line TL2 may overlap one another.

In other words, the first temporary boundary region defined by the first temporary boundary line TL1 and the second temporary boundary region defined by the second temporary boundary line TL2 may partially overlap one another to form an overlap region OR. The overlap region OR may be located within each of the first temporary boundary region and the second temporary boundary region. For example, the overlap region OR may be defined by a portion of the first temporary boundary line TL1 and a portion of the second temporary boundary line TL2.

A first boundary line DL1 may be formed by the first temporary boundary line TL1 and the second temporary boundary line TL2. The first boundary line DL1 may be a boundary line formed by merging the first temporary boundary line TL1 and the second temporary boundary line TL2, excluding the overlap region OR. For example, the first temporary boundary line TL1 excluding the overlap region OR may be a remainder of the first temporary boundary line TL1 excluding the portion of the first temporary boundary line TL1 that defines the overlap region OR. The second temporary boundary line TL2 excluding the overlap region OR may be a remainder of the second temporary boundary line TL2 excluding the portion of the second temporary boundary line TL2 that defines the overlap region OR. Therefore, the first boundary line DL1 may be formed by merging the remainder of the first temporary boundary line TL1 and the remainder of the second temporary boundary line TL2. That is, the forming of the first boundary line DL1 may include merging the first and second temporary boundary lines TL1 and TL2 that overlap one another.

Accordingly, the first boundary line DL1 may be spaced apart from the first analysis chip AC1 and the second analysis chip AC2. In a plan view, the first boundary line DL1 may surround each of the first analysis chip AC1 and the second analysis chip AC2, and may not overlap the first analysis chip AC1 and the second analysis chip AC2. For example, the first boundary line DL1 may be virtual boundary line formed by the program in the controller CTR based on the image of the substrate WF. Similar to the first and second temporary boundary lines TL1 and TL2, the first boundary line DL1 may be a virtual image formed in the program of the controller CTR, and the forming of the first boundary line DL1 may not be a direct marking of the substrate WF.

Referring to FIGS. 7, 11A, and 11B, a third temporary boundary line TL3 may be formed surrounding a third analysis chip AC3 located adjacent to the outer side surface WFS of the substrate WF. For example, the third analysis chip AC3 may be a chip that is in contact with the outer side surface WFS of the substrate WF. The third analysis chip AC3 may have an incomplete shape due to the outer side surface WFS of the substrate WF.

The third temporary boundary line TL3 may be spaced apart from edges of the third analysis chip AC3 in the first direction D1 and the second direction D2. For example, a separation distance SD between the third temporary boundary line TL3 and the third analysis chip AC3 may be about 3 mm. A third temporary boundary region defined by the third temporary boundary line TL3 may be formed larger than the third analysis chip AC3. For example, a planar size of the third temporary boundary region may be larger than a planar size of the third analysis chip AC3. As a result, a portion of the third temporary boundary line TL3 and a portion of the third temporary boundary region may be located outside of the substrate WF.

In other words, a portion of the third temporary boundary region located on the outer side surface WFS of the substrate WF may be formed as an outer region ER. The outer region ER may be a region not overlapping the substrate WF. For example, the outer region ER may be defined by a portion of the third temporary boundary line TL3 and the outer side surface WFS of the substrate WF.

A second boundary line DL2 may be formed by the third temporary boundary line TL3. The second boundary line DL2 may be the third temporary boundary line TL3 excluding the outer region ER. For example, the third temporary boundary line TL3 excluding the outer region ER may be a remainder of the third temporary boundary line TL3 excluding the portion of the third temporary boundary line TL3 that defines the outer region ER. That is, the forming of the second boundary line DL2 may include removing the portion of the third temporary boundary line TL3 that is located outside of the substrate WF.

As a result, at least a portion of the second boundary line DL2 may not be located outside of the substrate WF. In a plan view, the second boundary line DL2 may not be located on the outer side surface WFS of the substrate WF while surrounding the third analysis chip AC3. Similar to the first boundary line DL1, the second boundary line DL2 may be a virtual image formed in the program of the controller CTR.

Referring to FIGS. 4, 5, 7, and 12, the performing of the marking along the boundary line (S9) may include positioning the camera-marking assembly 130 so as to be adjacent to the substrate WF, bringing the marking device 133 of the camera-marking assembly 130 into contact with the substrate WF, moving the camera-marking assembly 130 along the boundary line in the first direction D1 and the second direction D2, and forming a marking line ML on the substrate WF.

The positioning of the camera-marking assembly 130 so as to be adjacent to the substrate WF, the bringing of the marking device 133 of the camera-marking assembly 130 into contact with the substrate WF, and the moving of the camera-marking assembly 130 along the boundary line in the first direction D1 and the second direction D2 may be substantially the same as those described with reference to FIGS. 4 and 5. That is, the marking device 133 may mark the substrate WF in an inkjet method while pressing the substrate WF at constant and appropriate pressure. Accordingly, the contamination of the substrate WF or damage to the chips of the substrate WF may be prevented.

As described with reference to FIGS. 10A and 10B, the boundary lines of adjacent analysis chips AC may be formed by merging the temporary boundary lines of adjacent analysis chips AC. As a result, the marking line ML formed along the boundary line may be spaced apart from the analysis chips AC adjacent to one another. That is, the marking line ML that overlaps the analysis chips AC may not be formed. Therefore, the contamination of the analysis chips AC due to the marking lines ML may be prevented.

As described with reference to FIGS. 11A and 11B, the boundary line of the analysis chip AC adjacent to the outer side surface WFS of the substrate WF may be formed by removing a portion of the temporary boundary line of the analysis chip AC located outside the substrate WF. Accordingly, the marking line ML formed along the boundary line may only be formed on the substrate WF. That is, the marking line ML may not be formed on the outer side surface WFS of the substrate WF. Therefore, the contamination of the side surface WFS of the substrate WF due to the marking line ML may be prevented.

The substrate marking method S according to embodiments of the disclosed concepts may include forming the temporary boundary line (S5) and forming the boundary line (S7), which are automatically performed by the program in the controller CTR. The boundary lines may be formed such that the analysis chips AC located adjacent to one another or the outer side surface WFS of the substrate WF are prevented from being contaminated by the marking lines ML formed along the boundary lines. Also, the pressure between the marking device 133 and the substrate WF may be maintained at a constant and appropriate level. Therefore, the substrate marking method S according to the disclosed concepts may mark the substrate WF automatically and efficiently without contaminating the substrate WF or damaging the chips CHP.

The substrate marking apparatus according to embodiments of the disclosed concepts may include the marking device for ejecting the ink in the inkjet method and the pressure sensor for measuring the pressure between the marking device and the substrate. Accordingly, the contamination of the substrate and damage to the chips on the substrate may be prevented.

The substrate marking method according to embodiments of the disclosed concepts may include forming the temporary boundary line and forming the boundary line, which are performed automatically by the program in the controller. The boundary lines may be formed such that the analysis chips located adjacent to one another or the outer surface of the substrate are prevented from being contaminated by the marking lines formed along the boundary lines.

Although embodiments of the disclosed concepts are described with reference to the accompanying drawings, those skilled in the art will appreciate that the present disclosure may be implemented in various other forms without departing from the technical spirit or essential features of the disclosure. Therefore, the above-described embodiments are to be considered in all aspects as illustrative and not restrictive.

What is claimed is:

1. A substrate marking apparatus comprising:
a stage configured to support a substrate;
a camera-marking assembly on the stage;
movement devices configured to move the camera-marking assembly; and
a controller electrically connected to the camera-marking assembly and the movement devices,
wherein the camera-marking assembly comprises:
a main body connected to the movement devices;
a marking device adjacent to the stage; and
a pressure sensor coupled to the main body.

2. The substrate marking apparatus of claim 1, wherein the movement devices comprise:
a first movement device comprising a first rail extending in a first direction;
a second movement device comprising a second rail extending in a second direction; and
a third movement device comprising a third rail extending in a third direction.

3. The substrate marking apparatus of claim 2, wherein the first direction and the second direction are parallel to an upper surface of the stage and perpendicular to one another, and
the third direction is perpendicular to the upper surface of the stage.

4. The substrate marking apparatus of claim 2, wherein the first movement device, the second movement device, and the third movement device are configured to move the camera-marking assembly in three dimensions.

5. The substrate marking apparatus of claim 1, wherein the pressure sensor is configured to measure a pressure between the substrate and the marking device.

6. The substrate marking apparatus of claim 5, wherein the controller is configured to control the movement devices based on the pressure.

7. The substrate marking apparatus of claim 1, wherein the pressure sensor is between the main body and the marking device.

8. The substrate marking apparatus of claim 1, wherein the camera-marking assembly comprises a camera coupled to the main body and spaced apart from the marking device.

9. The substrate marking apparatus of claim 1, wherein the marking device is configured to eject ink by an inkjet method.

10. A substrate marking method comprising:
preparing a substrate with a substrate marking apparatus;
identifying locations of the substrate and an analysis chip;
forming a temporary boundary line surrounding the analysis chip;
forming a boundary line from the temporary boundary line; and
marking the substrate along the boundary line,
wherein the substrate marking apparatus comprises:
a camera-marking assembly comprising a camera and a marking device;
movement devices connected to the camera-marking assembly; and
a controller electrically connected to the camera-marking assembly and the movement devices.

11. The substrate marking method of claim 10, wherein the identifying of the locations of the substrate and the analysis chip is performed by the camera of the camera-marking assembly.

12. The substrate marking method of claim 10, wherein each of the temporary boundary line and the boundary line comprises a virtual boundary line formed by a program in the controller.

13. The substrate marking method of claim 10, wherein the temporary boundary line is spaced apart from the analysis chip.

14. The substrate marking method of claim 10, wherein:
the analysis chip comprises a first analysis chip and a second analysis chip adjacent to one another,
the temporary boundary line comprises a first temporary boundary line surrounding the first analysis chip and a second temporary boundary line surrounding the second analysis chip, and
the first temporary boundary line and the second temporary boundary line overlap one another.

15. The substrate marking method of claim 14, wherein the forming of the boundary line comprises merging the first temporary boundary line and the second temporary boundary line.

16. The substrate marking method of claim 10, wherein the forming of the boundary line comprises removing a portion of the temporary boundary line located on an outer side surface of the substrate.

17. The substrate marking method of claim 10, wherein the marking of the substrate comprises bringing the marking device of the camera-marking assembly into contact with the substrate.

18. The substrate marking method of claim 17, wherein:
the camera-marking assembly comprises a main body and a pressure sensor between the main body and the marking device, and
the marking of the substrate comprises:
measuring, by the pressure sensor, a pressure between the marking device and the substrate; and
transmitting, by the camera-marking assembly, data about the pressure to the controller.

19. The substrate marking method of claim 18, wherein the marking of the substrate comprises controlling, by the controller, the movement devices based on the data about the pressure.

20. A substrate marking system comprising:
a load port configured to support a front opening unified pod (FOUP) storing a substrate;
a chamber connected to the load port and comprising a substrate marking apparatus; and
an interface module between the load port and the chamber,
wherein the substrate marking apparatus comprises:
a stage configured to support a substrate;
a camera-marking assembly on the stage; and
movement devices configured to move the camera-marking assembly, and
wherein the camera-marking assembly comprises a marking device, a pressure sensor, and a camera.
